(19) United States
(12) Patent Application Publication
(10) Pub. No.: US 2006/0231954 A1
(43) Pub. Date: Oct. 19, 2006

(54) Electric contact materials comprising organic heterojunction and device

(75) Inventors: Donghang Yan, Jilin Province (CN); Haibo Wang, Jilin Province (CN); Jun Wang, Jilin Province (CN); Jiguang Dai, Jilin Province (CN); Xiaoxia Jiang, Jilin Province (CN); Xuanjun Yan, Jilin Province (CN)

Correspondence Address: FISH & RICHARDSON PC, P.O. BOX 1022, MINNEAPOLIS, MN, 55440-1022, US

(73) Assignee: CHANGCHUN INSTITUTE OF APPLIED CHEMISTRY CHINESE ACADEMY OF SCIENCES

(21) Appl. No.: 11/217,983

(22) Filed: Sep. 1, 2005

(30) Foreign Application Priority Data
Apr. 18, 2005 (CN) 2005100167212

(51) Int. Cl. H01L 33/00

(52) U.S. Cl. 257/744; 257/103; 257/E33.062

(57) ABSTRACT

This invention relates to electric contact materials comprising organic heterojunction for improving the contact of organic semiconductor and metal electrode. The electric contact materials comprising organic heterojunction are composed of electron-type organic semiconductors, hole-type organic semiconductors and heterojunctions made thereof. The invention further relates to the organic diode, organic FET and organic photovoltaic device using the electric contact materials comprising organic heterojunction as a buffer layer.

### FIELD OF THE INVENTION

This invention relates to electric contact material comprising organic semiconductor (SC) heterojunction (HJ) for realizing the effective contact of metal electrode with organic SC. The invention further relates to the organic Field Effect Transistor (FET) device and organic photovoltaic device using electric contact materials comprising organic heterojunction as buffer layer.

### BACKGROUND OF THE INVENTION

Organic SC materials are extensively studied in recent years, and used widely in regard to the information display and photovoltaic cell applications. In China Patent 02129458.5, a sandwich-type organic FET is disclosed, and a method for forming new type SC from two or more kinds of organic SC materials is provided. By using this method, the overall performance of FET can be improved effectively, especially the threshold voltage can be reduced effectively. China Patent 03102064.x discloses a method for realizing ambipolar organic FET by using the organic SC HJ and a method for realizing normally-on FETs by using the conducting property of organic SC HJ. In “Chemical Physics Letter” vol 407, P87 (2005), Wangjun et. al. report that the interface of organic HJ has a high conductivity, and realizes normally-on and ambipolar FETs using a HJ. Therefore, the organic SC device containing the composite composed of two kinds of organic SC as an active layer, is distinct from single material in the device performance. In China Patent 200410010768.3, a method is provided for realizing the effective contact of metal electrode with SC by using a non-reactive buffer layer. In said method, the carrier injection efficiency in organic FET device is raised by using a material of high conductivity as buffer layer. In this invention, the organic HJ composed of two or more kinds of organic SC is used as electric contact material, and said electric contact materials comprising organic heterojunction are used in organic FET device and organic photovoltaic device to realize the effective contact of metal electrode with organic SC.

### DISCLOSURE OF THE INVENTION

One object of this invention is to provide an electric contact materials comprising organic heterojunction;

Another object of this invention is to provide an organic FET using electric contact materials comprising organic heterojunction as a buffer layer;

The third object of this invention is to provide an organic photovoltaic device using the electric contact materials comprising organic heterojunction as a buffer layer.

At the metal-organic SC interface, the charge in-out restriction has been overcome by the high conductivity thereof, said restriction is caused by the dipole effect and level mismatching at the metal-organic SC interface. Said high conductivity stems from the interface dipole produced by the contact of the organic SCs. Said interface dipole can form a very strong dipole field, and the carriers induced by the dipole field are cumulated at the interface to form a high conductive region. At said conductive region, the charge inject barrier has been reduced effectively, the tunnelling probability of the charge from metal electrode to organic SC has been enhanced. Therefore, the charge injection and extraction property can be improved markedly by using organic SC HJ as electric contact materials.

The electric contact materials comprising organic heterojunction are composed of electron-, hole-type organic SC and HJ thereof. Said hole-type SC layer is composed of one or at least two selected from the group consisting of copper phthalocyanine, nickel phthalocyanine, zinc phthalocyanine, cobalt phthalocyanine, platinum phthalocyanine, metal-free phthalocyanine, quaterthiophent, quinquethiophene, hexathiophene, 2,5-bis (4-biphenylyl) bithiophene, said electron-type SC layer are composed of one or at least two selected from the group consisting of copper hexadecafluoro-phthalocyanine, zinc hexadecafluoro-phthalocyanine, iron hexadecafluoro-phthalocyanine, cobalt hexadecafluoro-phthalocyanine and α,ω-diperfluorohexyl-6T. The method of vacuum molecular vapor deposition is used for preparing all the electric contact materials comprising organic heterojunction, the total thickness being 0˜50 nm.

The contact effect of metal electrode with organic SC can be improved effectively by using electric contact materials comprising organic heterojunction as buffer layer. The work function of the metal electrode preferably ranges from 4.3 eV to 5.7 eV. The metal electrode is one or more selected from the group consisting of ITO, Al, Mg, Ag, Ta, Cr, Mo, Cu, Au, and Pt. The contact resistance of the transistor using electric contact materials comprising organic heterojunction as buffer layer has been reduced markedly, thus the charge injection efficiency has been enhanced, and the device performance has been improved markedly. By employing the organic photovoltaic device using the electric contact materials comprising organic heterojunction as buffer layer, the effective extraction of the charge can be realized, and the device performance can be improved by a big margin.

### BRIEF DESCRIPTION OF THE DRAWINGS

FIG. 1a shows the schematic drawing of this invention's diode structure for electric contact material containing organic HJ used as buffer layer. In FIG. 1a, 1 represents substrate, 2 and 5 electrodes, 3 organic SC active layer, 4 buffer layer formed from a electric contact material containing organic HJ.

FIG. 1b shows the schematic drawing of the diode structure free of buffer layer, wherein, 1 represents substrate, 2 and 4 electrodes, 3 organic SC active layer.

FIG. 1c shows current-voltage characteristic of example 1's diode structure for electric contact material containing organic HJ used as buffer layer on dark (curve b) and illuminated (curve c) conditions, and current-voltage characteristic of the diode structure free of buffer layer on dark (curve a) condition.

FIG. 2a shows the schematic drawing of organic FET structure for electric contact material containing organic HJ used as buffer layer, wherein, 1 represents substrate, 2 gate electrode, 3 insulation layer, 4 organic SC active layer, 5 buffer layer formed from a electric contact material containing organic HJ, 6 source/drain electrodes. FIG. 2a is the figure for the abstract as well.

FIG. 2b shows the output characteristics of example 2's FET.

FIG. 2c shows the transfer characteristics of example 2's FET.

FIG. 3a shows the schematic drawing of organic photovoltaic structure for electric contact material containing organic HJ used as buffer layer, wherein, 1 represents substrate, 2 and 6 electrodes, 3 buffer layer formed from a electric contact material containing organic HJ, 4 and 5 organic SC active layer.

FIG. 3b shows the current-voltage characteristic of example 3's organic photovoltaic device (buffer layer-free) on dark (curve (a)) and illuminated (curve (b)) conditions, and that of organic photovoltaic device (buffer layer-containing) on dark (curve c) and illuminated (curve d) conditions.

### PREFERRED EMBODIMENTS OF THE INVENTION

Hereinafter, this invention is described with reference to the figures.

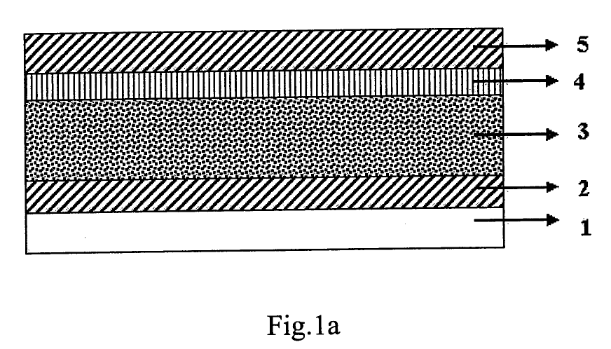

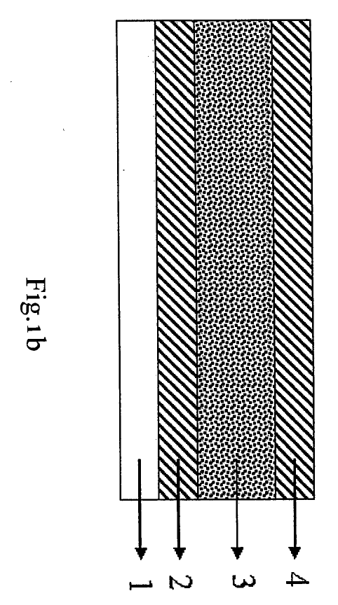

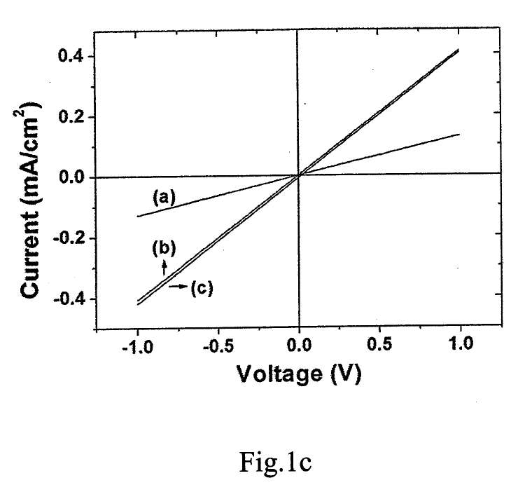

FIG. 1a is the schematic drawing of a diode structure for the electric contact material containing organic HJ used as a buffer layer. A conducting material is provided on substrate 1 to form electrode 2; hole-type and/or electron-type SC materials are provided on the electrode 2 to form organic active layer 3; hole-type and/or electron-type SC materials are provided on the organic active layer 3 to form electric contact material containing organic HJ so as to form buffer layer 4; and electrode 5 is provided on the buffer layer 4.

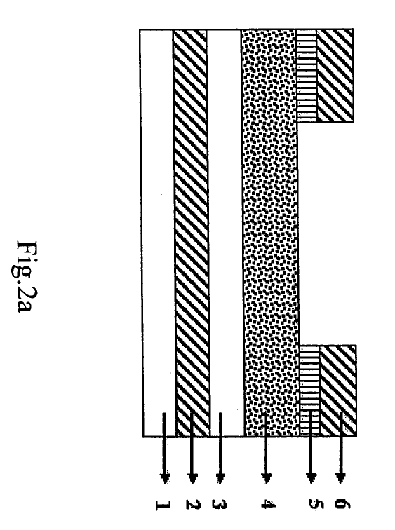

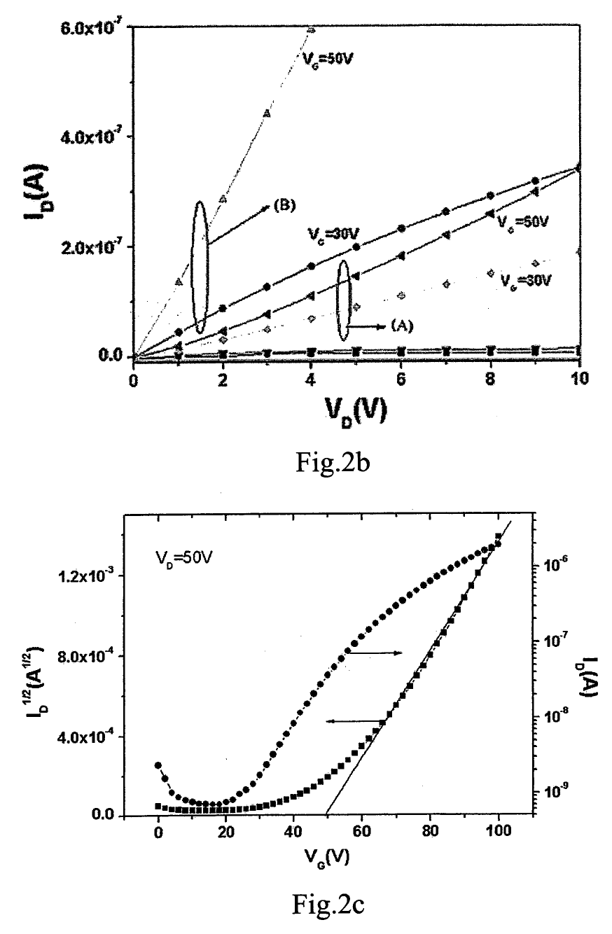

FIG. 2a is the schematic drawing of an organic FET structure for the electric contact material containing organic HJ used as buffer layer. A conducting material is provided on the substrate 1 to form the gate electrode 2, the insulation material is provided on the gate electrode 2 to form the insulation layer 3, electron-type and/or hole-type SC materials are provided on the insulation layer 3 to form SC active layer 4, hole-type and/or electron-type SC materials are provided on the SC active layer 4 to form the electric contact material containing organic HJ and thus form the buffer layer 5, the source/drain electrode 6 is provided on the buffer layer 5.

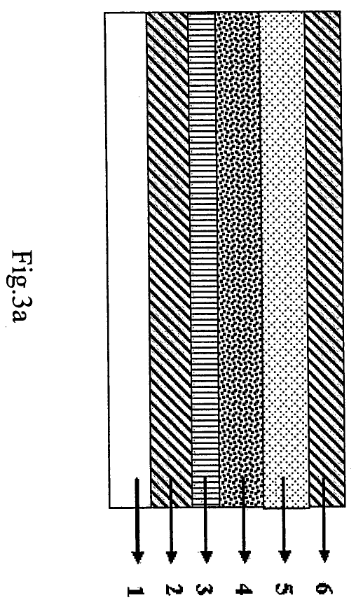

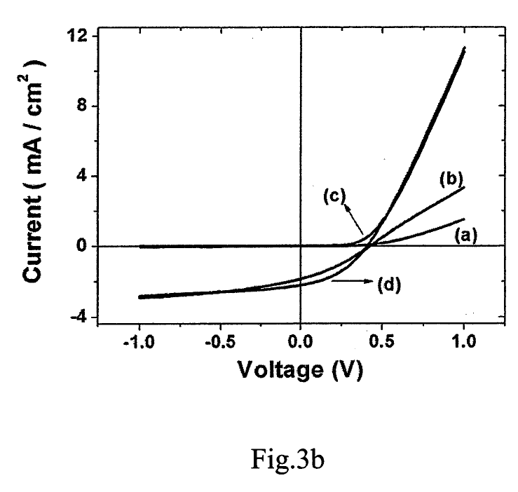

FIG. 3a is the schematic drawing of an organic photovoltaic structure for the electric contact material containing organic HJ used as buffer layer. A conducting material is provided on the substrate 1 to form the electrode 2, hole-type and/or electron-type SC materials are provided on the electrode 2 to form the electric contact material containing organic HJ to form buffer layer 3, the SC active layer 4 is provided on the buffer layer 3, the SC active layer 5 is provided on the SC active layer 4, the electrode 6 is provided on the SC active layer 5.

In the following, this invention is further described by the examples.

### EXAMPLE 1

The commercial products—copper phthalocyanine (CuPc), zinc phthalocyanine (ZnPc) nickel phthalocyanine (NiPc), cobalt phthalocyanine (CoPc), metal-free phthalocyanine (H₂Pc), platinium phthalocyanine (PtPc), copper hexadecafluoro-phthalocyanine (F₁₆CuPc), zinc hexadecafluoro-phthalocyanine (F₁₆ZnPc), iron hexadecafluoro-phthalocyanine (F₁₆FePc) and cobalt hexadecafluoro-phthalocyanine (F₁₆CoPc) are used after sublimation and purification. The synthetic materials—quaterthiophent (4T), quinquethiophene (5T), hexathiophene (6T), 2,5-bis (4-biphenylyl) bithiophene (BP2T) and α,ω-diperfluorohexyl-6T (DFH-6T) are used after sublimation and purification. The glass covering conducting film indium-tin oxide (ITO), as a whole is a commercial product. Here, indium-tin oxide (ITO) is covered on glass substrate 1 and used as electrode 2.

An electric contact material containing organic HJ is used as a buffer layer of the diode structure (see FIG. 1a). A method of vacuum molecular vapor deposition (pressure 10⁻⁵ Pa) is used for preparing all the organic layers. The ITO electrode on the glass substrate is formed into electrode 2 as the anode. Firstly, 40 nm of zinc phthalocyanine is deposited on ITO electrode 2 by the method of vacuum molecular vapor deposition to form the organic SC active layer 3. Then a electric contact material containing organic HJ is deposited on the organic SC active layer 3 by the method of vacuum molecular vapor deposition to form buffer layer 4. Said electric contact material consists of the organic SCs of electron-type SC, hole-type SC and the HJs formed therefrom, wherein the hole-type SC layer is comprised of one or at least two selected from the group consisting of CuPc, NiPc, ZnPc, CoPc, PtPc, H₂Pc, quaterthiophent (4T), quinquethiophene (5T), hexathiophene (6T), 2,5-bis (4-biphenylyl) bithiophene (BP2T); the electron-type SC layer is comprised of one or at least two selected from the group consisting of copper hexadecafluoro-phthalocyanine, zinc hexadecafluoro-phthalocyanine, iron hexadecafluoro-phthalocyanine, cobalt hexadecafluoro-phthalocyanine and α,ω-diperfluorohexyl-6T. The method for preparing buffer layer 4 is that, firstly, one type of organic SC is deposited by the method of vacuum molecular vapor deposition (substrate 150° C., thickness 2 nm) to form a discrete crystal grain, then another type of organic SC is deposited under the same condition by the same method (thickness 2 nm), the two types of SC form the organic HJ with interpenetrate network structure and produce a electric contact material containing organic HJ used as buffer layer, finally, different metals are deposited on buffer layer 4 by the method of vacuum thermal deposition (pressure 10⁻⁴Pa) to form electrode 5 as cathode.

In order to clarify the effect of buffer layer on improving the contact performance, a buffer layer-free device has been fabricated (see FIG. 1b). All the organic layers are prepared by the method of vacuum molecular vapor deposition (pressure 10⁻⁵ Pa). The ITO on glass substrate 1 is used as anode to form the electrode 2. Firstly, 40 nm of ZnPc is deposited on the electrode 2 by the method of vacuum molecular vapor deposition to form an organic SC active layer 3. Then, different metals are deposited on the organic SC active layer 3 by the method of vacuum thermal deposition (pressure 10⁻⁴ Pa) to form the electrode 4 as cathode.

Tab. 1 listed the conductivities of said two kinds of structural devices having metal electrode with low work function in FIG. 1a and FIG. 1b. Wherein anode +1 volt, eV electron-volt, S/cm siemens per centimeter. For the metal with low work function, Mg and Al, both the buffer layer-free and buffer layer-containing devices show the Shottky contact. But compared with the buffer layer-free device, the conductivity of all the corresponding buffer layer-containing devices has increased to some extent.

TABLE 1

| | | work | | | |
|---|---|---|---|---|---|
| | | function | | | |
| | | of | Conductivity (S/cm) | | |
| | cath- | cathode | | buffer- | contact |
| buffer layer | ode | (eV) | buffer-free | contg. | performance |
| ZnPc/F₁₆CuPc | Mg | 2.87 | 1.1 × 10⁻⁸ | 2.5 × 10⁻⁸ | Shottky contact |
| ZnPc/F₁₆CuPc | Al | 4.28 | 0.8 × 10⁻⁸ | 1.6 × 10⁻⁸ | Shottky contact |
| CuPc/F₁₆CuPc | Al | 4.28 | 1.0 × 10⁻⁸ | 3.1 × 10⁻⁸ | Shottky contact |
| 6T/DFH-6T | Al | 4.28 | 6.1 × 10⁻⁸ | 1.2 × 10⁻⁷ | Shottky contact |
| 6T/CuPc/ | Al | 4.28 | 4.4 × 10⁻⁸ | 8.3 × 10⁻⁸ | Shottky contact |
| F₁₆CuPc | | | | | |
| BP2T/F₁₆CuPc | Al | 4.28 | 5.4 × 10⁻⁸ | 2.1 × 10⁻⁷ | Shottky contact |

Tab. 2 listed the conductivities of said two kinds of structural devices having metal electrode with high work function in FIG. 1a and FIG. 1b. For the electrode with the work function between 4.3eV˜5.1 eV—Ag, Ta, Cr, Mo and Cu, the conductivities of all the buffer layer-containing devices are 2˜3 times higher than that of the buffer layer-free devices and all show the ohmic transfer. For the metal electrode with yet higher work function—Au and Pt, the electrical performance of all the structures shows the ohmic contact, the conductivity of the buffer layer-containing devices has increased slightly. Therefore, the buffer layer formed from Electric contact materials comprising organic heterojunction is capable of effectively improving the contact between metal electrode and organic SC, the scope of application is a scope wherein all the electrode materials have the work function larger than 4.3 eV but less than 5.7 eV.

TABLE 2

| | | work | | | |
|---|---|---|---|---|---|
| | | function | | | |
| | | of | | | |
| | | cathode | Conductivity (S/cm) | | contact |
| buffer layer | cathode | (eV) | buffer-free | buffer-contg. | performance |
| ZnPc/F₁₆CuPc | Ag | 4.26 | 5.2 × 10⁻¹⁰ | 1.6 × 10⁻⁹ | ohmic contact |
| CuPc/F₁₆CuPc | Ag | 4.26 | 2.7 × 10⁻⁹ | 3.8 × 10⁻⁸ | ohmic contact |
| PtPc/F₁₆ZnPc | Ag | 4.26 | 4.1 × 10⁻¹⁰ | 1.1 × 10⁻⁹ | ohmic contact |
| 5T/F₁₆CuPc | Ag | 4.26 | 3.6 × 10⁻⁹ | 6.9 × 10⁻⁹ | ohmic contact |
| 4T/DFH-6T | Ag | 4.26 | 8.9 × 10⁻⁸ | 7.2 × 10⁻⁷ | ohmic contact |
| BP2T/F₁₆ZnPc | Ag | 4.26 | 1.3 × 10⁻⁷ | 8.8 × 10⁻⁷ | ohmic contact |
| NiPc/F₁₆CoPc | Ag | 4.26 | 2.1 × 10⁻⁹ | 5.8 × 10⁻⁸ | ohmic contact |
| ZnPc/CuPc/F₁₆CuPc | Ag | 4.26 | 4.2 × 10⁻⁹ | 6.9 × 10⁻⁸ | ohmic contact |
| 4T/5T/DFH-6T | Ag | 4.26 | 9.1 × 10⁻⁸ | 8.0 × 10⁻⁷ | ohmic contact |
| CuPc/F₁₆CuPc/F₁₆ZnPc | Ag | 4.26 | 6.2 × 10⁻⁹ | 7.5 × 10⁻⁸ | ohmic contact |
| ZnPc/F₁₆CuPc | Ta | 4.25 | 2.1 × 10⁻⁹ | 6.2 × 10⁻⁹ | ohmic contact |
| CuPc/F₁₆FePc | Ta | 4.25 | 1.0 × 10⁻⁹ | 3.1 × 10⁻⁹ | ohmic contact |
| H₂Pc/F₁₆FePc | Ta | 4.25 | 7.0 × 10⁻¹⁰ | 1.5 × 10⁻⁹ | ohmic contact |
| NiPc/CuPc/F₁₆CuPc | Ta | 4.25 | 6.8 × 10⁻⁹ | 9.1 × 10⁻⁹ | ohmic contact |
| ZnPc/F₁₆CuPc | Cr | 4.5 | 2.9 × 10⁻⁸ | 8.4 × 10⁻⁸ | ohmic contact |
| CoPc/F₁₆ZnPc | Cr | 4.5 | 1.1 × 10⁻⁸ | 7.3 × 10⁻⁸ | ohmic contact |
| 4T/DFH-6T | Cr | 4.5 | 9.1 × 10⁻⁸ | 8.7 × 10⁻⁷ | ohmic contact |
| ZnPc/F₁₆CuPc | Mo | 4.6 | 2.8 × 10⁻⁸ | 9.1 × 10⁻⁸ | ohmic contact |
| PtPc/F₁₆CuPc | Mo | 4.6 | 3.3 × 10⁻⁸ | 1.3 × 10⁻⁷ | ohmic contact |
| 5T/DFH-6T | Mo | 4.6 | 5.3 × 10⁻⁷ | 7.7 × 10⁻⁶ | ohmic contact |
| ZnPc/F₁₆CuPc | Cu | 4.65 | 5.3 × 10⁻⁸ | 1.3 × 10⁻⁷ | ohmic contact |
| H₂Pc/F₁₆ZnPc | Cu | 4.65 | 4.1 × 10⁻⁸ | 8.6 × 10⁻⁸ | ohmic contact |
| CuPc/F₁₆FePc | Cu | 4.65 | 3.0 × 10⁻⁸ | 7.5 × 10⁻⁸ | ohmic contact |
| CoPc/F₁₆CuPc | Cu | 4.65 | 4.9 × 10⁻⁸ | 1.3 × 10⁻⁷ | ohmic contact |
| BP2T/F₁₆CuPc | Cu | 4.65 | 7.5 × 10⁻⁸ | 3.1 × 10⁻⁷ | ohmic contact |
| NiPc/CuPc/F₁₆ZnPc | Cu | 4.65 | 4.5 × 10⁻⁸ | 8.1 × 10⁻⁸ | ohmic contact |
| CoPc/ZnPc/F₁₆ZnPc | Cu | 4.65 | 6.2 × 10⁻⁸ | 9.8 × 10⁻⁸ | ohmic contact |
| ZnPc/F₁₆ZnPc/DFH-6T | Cu | 4.65 | 8.5 × 10⁻⁷ | 9.4 × 10⁻⁶ | ohmic contact |
| ZnPc/F₁₆CuPc | Au | 5.1 | 1.0 × 10⁻⁷ | 1.1 × 10⁻⁷ | ohmic contact |
| CuPc/F₁₆CuPc | Au | 5.1 | 1.2 × 10⁻⁷ | 1.4 × 10⁻⁷ | ohmic contact |
| CoPc/F₁₆CoPc | Au | 5.1 | 9.4 × 10⁻⁸ | 1.1 × 10⁻⁷ | ohmic contact |
| CuPc/F₁₆ZnPc | Au | 5.1 | 1.1 × 10⁻⁷ | 1.1 × 10⁻⁷ | ohmic contact |
| 6T/F₁₆CuPc | Au | 5.1 | 2.9 × 10⁻⁷ | 3.1 × 10⁻⁷ | ohmic contact |
| 6T/F₁₆ZnPc | Au | 5.1 | 2.8 × 10⁻⁷ | 3.3 × 10⁻⁷ | ohmic contact |
| 6T/DFH-6T | Au | 5.1 | 8.2 × 10⁻⁷ | 9.2 × 10⁻⁷ | ohmic contact |
| BP2T/F₁₆CuPc | Au | 5.1 | 2.2 × 10⁻⁷ | 2.5 × 10⁻⁷ | ohmic contact |
| 6T/CuPc/F₁₆CuPc | Au | 5.1 | 2.6 × 10⁻⁷ | 3.1 × 10⁻⁷ | ohmic contact |
| CoPc/CuPc/F₁₆CuPc | Au | 5.1 | 2.0 × 10⁻⁷ | 2.2 × 10⁻⁷ | ohmic contact |
| CuPc/F₁₆CuPc/F₁₆CoPc | Au | 5.1 | 2.1 × 10⁻⁷ | 2.4 × 10⁻⁷ | ohmic contact |
| ZnPc/F₁₆CuPc | Pt | 5.65 | 1.2 × 10⁻⁷ | 1.2 × 10⁻⁷ | ohmic contact |
| ZnPc/F₁₆ZnPc | Pt | 5.65 | 1.1 × 10⁻⁷ | 1.1 × 10⁻⁷ | ohmic contact |
| CoPc/F₁₆FePc | Pt | 5.65 | 1.0 × 10⁻⁷ | 9.7 × 10⁻⁸ | ohmic contact |
| CuPc/F₁₆CuPc | Pt | 5.65 | 2.1 × 10⁻⁷ | 2.5 × 10⁻⁷ | ohmic contact |
| NiPc/F₁₆ZnPc | Pt | 5.65 | 8.0 × 10⁻⁸ | 8.1 × 10⁻⁸ | ohmic contact |
| 6T/DFH-6T | Pt | 5.65 | 1.1 × 10⁻⁶ | 1.3 × 10⁻⁶ | ohmic contact |
| CoPc/CuPc/F₁₆CuPc | Pt | 5.65 | 1.4 × 10⁻⁷ | 1.5 × 10⁻⁷ | ohmic contact |
| H₂Pc/CuPc/F₁₆CuPc | Pt | 5.65 | 1.3 × 10⁻⁷ | 1.4 × 10⁻⁷ | ohmic contact |

FIG. 1c showed the current-voltage characteristic of said two kinds of structural devices shown in FIG. 1a, FIG. 1b. For the device of FIG. 1a, the ITO is formed into electrode 2 as the anode, ZnPc is deposited to form an organic SC active layer 3, ZnPc and F₁₆CuPc are deposited to form a buffer layer 4, and electrode 5 is an Ag electrode. For the device of FIG. 1b, the ITO is formed into electrode 2, the organic SC active layer 3 is ZnPc, electrode 4 is Ag electrode as the cathode. The current increases linearly with the increase in voltage, that is to say, the contact is ohmic contact. On dark condition, the conductivity of the buffer layer-containing structure is clearly higher than that of buffer layer-free structure. On illuminated condition, the current-voltage characteristic of the buffer layer-containing structure nearly coincided with that on dark condition, that is to say, it is insensitive to light. The insensitivity to light makes it suitable for organic photovoltaic device.

### EXAMPLE 2

The commercial products of CuPc and F₁₆CuPc are used after sublimation and purification. A electric contact material containing organic HJ is used as a buffer layer of the organic FET structure (see FIG. 2a). A layer of Ta metal film is plated on the 7059 glass substrate by the method of RF magnetic control sputtering (background vac 2×10⁻³ Pa, Ar gas pressure 1 Pa, RF power 500 W), and photoetched into the gate electrode 2. A layer (300 nm) of Ta₂O₅ reactive sputter is sputtered continuously on the gate electrode 2 by the method of DC magnetic control sputtering (background vac 2×10³ Pa, O₂ gas pressure 0.9 Pa, DC power 500 W), used as an insulation layer 3. Then, 30 nm of CuPc is deposited on the insulation layer 3 by the method of molecular vapor deposition (pressure 10⁻⁴ Pa) to form the organic SC active layer 4; about 2 nm of F₁₆CuPc film is deposited continuously through a mask on the organic SC active layer 4 (the method and condition are the same as said above) to form the electric contact material containing organic HJ with a interpenetrate network structure, used as the buffer layer 5; Finally, 60 nm of Au is deposited on the buffer layer 5 by the method of vacuum thermal evaporation (pressure 10⁻⁴ Pa) to form the source/drain electrode 6.

The output characteristic of the buffer layer (i.e. Electric contact materials comprising organic heterojunction)-containing and buffer layer-free organic FET is showed in FIG. 2b. Wherein, the two curves in ring (A) are for the buffer layer-free device and those in ring (B) are for the buffer layer-containing device. On the low drain voltage, the current shows a linear increase. When the gate voltage V_{G} are 30 V, 50 V respectively, as can be seen by comparing the two curves, under V_{D} less than 10 V, higher I_{D} is showed by the device with Electric contact materials comprising organic heterojunction. Meanwhile it can be seen from FIG. 2b, the contact resistance showed by the device with HJ-containing electric contact material is markedly reduced. The transfer characteristic of corresponding organic FET device is showed in FIG. 2c, the I_{D} depends markedly on the V_{G}. The electrical parameters of the organic FET with Electric contact materials comprising organic heterojunction have been extracted from the transfer curves in FIG. 2c. The field-effect hole mobility in the saturation region is 0.014 cm²V⁻¹S⁻¹, on-off current ratio is 4×10³.

### EXAMPLE 3

The commercial products of F₁₆CuPc, ZnPc and fullerene (C₆₀) are used after sublimation and purification. The glass covering conducting film ITO which is covered on the glass substrate 1 as the electrode 2 is a commercial product as a whole.

FIG. 3a is the structure of an organic photovoltaic device with Electric contact materials comprising organic heterojunction as buffer layer. A method of vacuum molecular vapor deposition (pressure 10⁻⁵ Pa) is used for preparing all the organic layers. Firstly, the buffer layer 3 (4 nm) is prepared on the ITO electrode 2, the buffer layer 3 consists of organic SC material—F₁₆CuPc and ZnPc. F₁₆CuPc is deposited by the method of vacuum molecular vapor deposition (substrate 150° C., thickness 2 nm) to form discrete crystal grains, then the ZnPc is deposited (2 nm), according to the same method and condition as said above, to produce a electric contact material containing organic HJ with a interpenetrate network structure, used as buffer layer 3. Then, the ZnPc is deposited on buffer layer 3, according to the same method and condition as said above, to form the organic SC active layer 4. The C₆₀ is deposited on the organic SC active layer 4, according to the same method and condition as said above, to form the organic SC active layer 5. Finally, the metal electrode Al is deposited on the organic SC active layer 5 by the method of vacuum thermal evaporation (pressure 10⁻⁴ Pa) to form the electrode 6.

FIG. 3b is the current-voltage characteristic curve of the buffer layer (i.e. organic SC HJ)-containing and buffer layer-free organic photovoltaic devices on dark and illuminated condition. The illuminated condition is simulation sunlight AM 1.5, and the intensity of illumination is 100 mW/cm². For the buffer layer-containing photovoltaic device, on dark condition, the current at negative bias is very weak, at positive bias increases rapidly with the increase in voltage, and shows the excellent diode rectification characteristic (see FIG. 3b, curve c). On illuminated condition, the device shows photovoltaic characteristic (see FIG. 3b, curve d). FIG. 3b, curves a and b are the current-voltage characteristics of the buffer layer-free organic photovoltaic device on dark and illuminated conditions. The performance parameters of the buffer layer-containing and buffer layer-free organic photovoltaic device are listed in Tab. 2.

TAB. 2

| performance Parameter | buffer-free | buffer-contg. |
|---|---|---|
| V_{oc} (V) | 0.44 | 0.42 |
| I_{sc} (mA/cm²) | 1.87 | 2.22 |
| FF | 0.31 | 0.38 |
| η (%) | 0.25 | 0.35 |
| Rₛ (ohmic/cm²) | 185 | 45 |
| Rₛₕ (ohmic/cm²) | 500 | 667 |

This invention is not limited to the above-mentioned examples. In general, the electric contact materials containing organic SC HJ used as buffer layer disclosed by this invention can be used in other organic SC device. Those devices can form two- and three-dimensional devices in integrated circuit. These integrated devices can be used in the flexible integrated circuit, active matrix display, and photovoltaic cell etc. The low-temperature processing can be realized by using the electronic device of this invention.

1. Electric contact materials comprising organic heterojunction, wherein said electric contact materials comprising organic heterojunction being composed of electron-type organic semiconductors, hole-type organic semiconductors and heterojunctions made thereof.

2. The electric contact materials comprising organic heterojunction according to claim 1, wherein said electron-type organic semiconductors and hole-type organic semiconductors are derivatives of the same family.

3. The electric contact materials comprising organic heterojunction according to claim 2, wherein said hole-type organic semiconductor layer is comprised of one or at least two selected from the group consisting of copper phthalocyanine, nickel phthalocyanine, zinc phthalocyanine, cobalt phthalocyanine, platinium phthalocyanine, and metal-free phthalocyanine; said electron-type organic semiconductor layer is comprised of one or at least two selected from the group consisting of copper hexadecafluoro-phthalocyanine, zinc hexadecafluoro-phthalocyanine, iron hexadecafluoro-phthalocyanine and cobalt hexadecafluoro-phthalocyanine.

4. The electric contact materials comprising organic heterojunction according to claim 2, wherein said hole-type organic semiconductor layer is comprised of one or at least two selected from the group consisting of thiophene oligomer, polythiophene, 2,5-bis (4-biphenylyl) bithiophene, said electron-type organic semiconductor layer is comprised of α,ω-diperfluorohexyl-6T.

5. A metal electrode in contact of the organic heterojunction-containing electric contact material according to claim 1, wherein the work function of said electrode is higher than 4.3 eV but less than 5.7 eV.

6. A metal electrode according to claim 5, wherein the metal is one or more selected from the group consisting of ITO, Al, Mg, Ag, Ta, Cr, Mo, Cu, Au, and Pt.

7. An organic field effect transistor using the electric contact materials comprising organic heterojunction according to claim 1 as buffer layer, comprising: substrate (1), gate electrode (2) formed on the substrate (1), gate insulation layer (3) formed on the gate electrode (2), organic semiconductor active layer (4) formed on the gate insulation layer (3), buffer layer (5) composed of the electric contact materials comprising organic heterojunction and being in contact with the organic semiconductor active layer (4), and source/drain electrode (6) in contact with buffer layer (5).

8. An organic film photovoltaic cell using an electric contact materials comprising organic heterojunction according to claim 1 as buffer layer, comprising: a substrate (1), a transparent electrode (2) formed on the substrate (1), a buffer layer (3) composed of the organic heterojunction-containing electric contact material and being formed on the transparent electrode (2), an organic semiconductor active layer (4) formed on the buffer layer (3), an organic semiconductor active layer (5) formed on the organic semiconductor active layer (4), a metal electrode (6) formed on the organic semiconductor active layer (5).
